(19) United States
(12) Patent Application Publication
(10) Pub. No.: US 2025/0308981 A1
(43) Pub. Date: Oct. 2, 2025

(54) METHOD FOR FORMING CAULKING LAYER, METHOD OF MANUFACTURING ELECTRONIC DEVICE AND SEMICONDUCTOR DEVICE THEREOF

(71) Applicant: TAIWAN SEMICONDUCTOR MANUFACTURING COMPANY, LTD., Hsinchu (TW)

(72) Inventors: Hung-Yu YEN, Hsinchu (TW); Yu-Yun PENG, Hsinchu (TW); Keng-Chu LIN, Hsinchu (TW)

(73) Assignee: TAIWAN SEMICONDUCTOR MANUFACTURING COMPANY, LTD., Hsinchu (TW)

(21) Appl. No.: 18/617,963

(22) Filed: Mar. 27, 2024

(51) Int. Cl. H01L 21/762; H01L 29/06; H01L 29/423; H01L 29/775; H01L 29/786

(52) U.S. Cl. CPC H01L 21/76224; H10D 30/43; H10D 30/6735; H10D 30/6757; H10D 62/121

(57) ABSTRACT

A processing device for forming a caulking layer is provided. The processing device includes a processing chamber and an ultraviolet illumination device. The processing chamber includes a carrying platform and a caulking device. The carrying platform is configured to carry a substrate, and the substrate has a patterned recess. The caulking device is configured to inject or deposit a flowable sealant into the patterned recess to form a caulking layer. The ultraviolet illumination device is configured to irradiate ultraviolet rays on the caulking layer to solidify the caulking layer in the patterned recess.

### BACKGROUND

In the process of manufacturing integrated circuits, trenches or gaps are often filled with insulating materials. For example, shallow trench isolation, cut metal gate refill, cut poly refill, and fork sheet sidewalls etc. all need to be filled with insulating materials. Traditional processes typically use oxide film to seal the trench or gap. However, with the miniaturization of the line pitch of large-scale integration (LSI) devices and the limited caulking space of high-aspect-ratio trenches (e.g., the aspect ratio is greater than 10), the oxide film cannot seal the gap well. The oxide film is broken after post-etching and damaged during the process of manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic diagrams of a processing device according to an embodiment of the present disclosure.

FIG. 2 is a flow chart of a method for forming a caulking layer according to an embodiment of the present disclosure.

FIGS. 3A to 3E are schematic diagrams of a method for forming a caulking layer.

FIGS. 4A to 4D are schematic diagrams of a method of manufacturing an electronic device according to an embodiment of the present disclosure.

FIGS. 5A to 5E are schematic diagrams of a method of manufacturing an electronic device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Examples described herein relate to a method and a processing device for performing multiple processes on a flowable gap-filling film deposited on a substrate in the same processing chamber. The processes may include dispensing or depositing a gap-filling film by a flowable process and curing the gap-filling film.

The processes described herein on flowable gap-filling films can improve the quality of the gap-filling films. The flowable gap-filling films are widely used due to their ability to fill gaps, especially high aspect ratio gaps (e.g., the aspect ratio is greater than 10). Previous gap-filling films often have undesirable qualities, including seams or voids in the gap. For example, the oxidation diffusion of a film can vary based on the filling depth of the film due to non-uniformity of oxidation diffusion of the gap-filling film. The examples described herein can improve the quality of gap-filling films, such as improving the uniformity of film deposition. Improving the uniformity of film deposition can avoid voids or seams in the trenches. Additionally, less processing can be performed on the gap-filling films to achieve this benefit, which can further reduce processing time. Reduced processing time can in turn reduce the cost of manufacturing the final product. Additionally, in some applications, higher quality gap-filling films can improve the electrical characteristics of semiconductor devices. These and/or other benefits may be achieved according to various embodiments.

Various examples are described below. A curable sealant is formed in the shallow trench isolations (STIs) between fins on the substrate, or a curable sealant is formed in the gap between two gate structures on the substrate, or a curable sealant is formed within any patterned recesses on the substrate. The caulking layer formed by this process can be implemented, for example, in a fin field effect transistor (FinFET). These examples are provided to understand the various aspects. Other examples can be implemented in different contexts. For example, some examples may be implemented with any film deposited on any substrate structure by a flowable process (e.g., flowable chemical vapor deposition (FCVD) or spin coating). Although various features of different examples are described together in a process flow or system, the various features may each be implemented separately or individually and/or in a different process flow or different system. Additionally, various processes are described as being performed sequentially; other examples may implement the processes in a different order and/or with more or fewer operations.

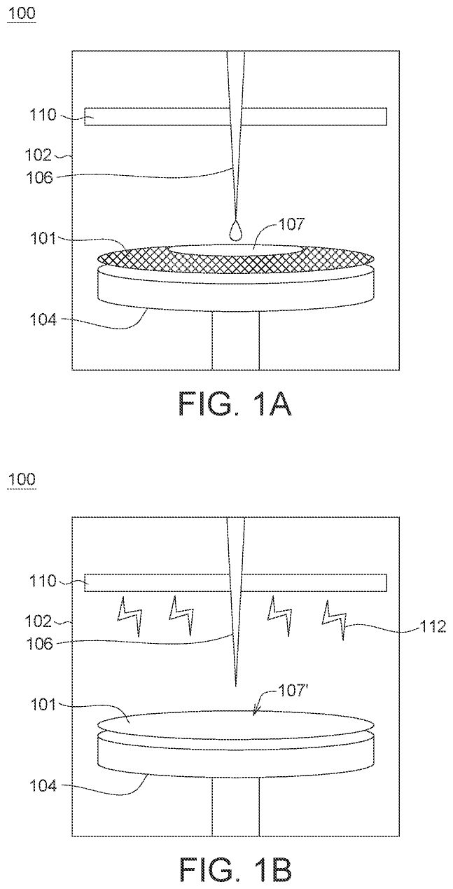

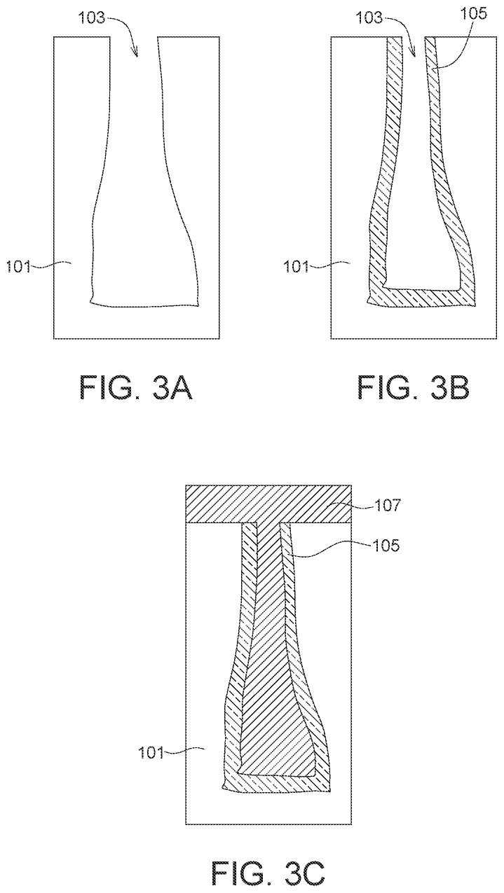

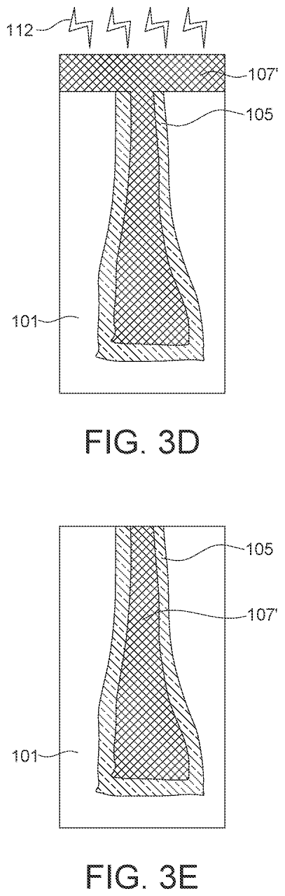

Referring to FIGS. 1A and 1B, schematic diagrams of a processing device 100 for forming a caulking layer 107′ according to an embodiment of the present disclosure are illustrated. As shown in FIG. 1A, the processing device 100 includes a processing chamber 102 and an ultraviolet illumination device 110. The processing chamber 102 includes a carrying platform 104 and a caulking device 106. The carrying platform 104 is configured to carry a substrate 101, and the substrate 101 has a patterned recess 103 (see FIG. 3A). The caulking device 106 is configured to inject or deposit a flowable sealant 107 into the patterned recess 103 to form a caulking layer 107′, and the ultraviolet illumination device 110 is configured to irradiate ultraviolet rays 112 on the caulking layer 107′ to solidify the caulking layer 107′ in the patterned recess 103.

The processing chamber 102 may be a vacuum chamber or a chamber containing an inert gas. Although the figures are not shown, a gas delivery and pressure control system (e.g., including a plurality of vacuum pumps) is provided in communication with the processing chamber 102 to independently regulate the pressure in the processing chamber 102. The gas delivery and pressure control system may include one or more gas pumps, gas sources, various valves, and conduits coupled to the processing chamber 102. The gas delivery and pressure control system can maintain the processing chamber 102 at a target pressure.

The substrate 101 is, for example, a wafer. The substrate 101 can be transported into the processing chamber 102 and placed on the carrying platform 104. The processing chamber 102 can perform a series of operations to perform specified processing on the substrate 101, such as rotating the carrying platform 104 to spin-coat the substrate 101, or depositing a sealant 107 on the substrate 101. The sealant 107 is, for example, a light-curable glue or a thermal-curable glue. As shown in FIGS. 1A and 1B, the caulking device 106 is, for example, a glue dispenser, which evenly applies the sealant 107 on the substrate 101. In another embodiment, the caulking device 106 is, for example, a chemical vapor deposition device, which uniformly deposits the sealant 107 on the substrate 101.

In addition, an ultraviolet illumination device 110 is provided in the processing chamber 102 for irradiating ultraviolet rays 112 on the caulking layer 107′ to solidify the caulking layer 107′ in the patterned recess 103. Therefore, it is not necessary to form a silicon oxide gap-filling film through traditional oxidation treatment.

In another embodiment, a heating device (such as a coil heater) is provided in the processing chamber 102 to heat the caulking layer 107′ to solidify the caulking layer 107′ in the patterned recess 103.

For example, traditional oxidation treatment is a thermal oxidation treatment or a plasma oxidation treatment. In the thermal oxidation process, oxygen-containing processing gas, such as oxygen (O₂), ozone gas (O₃), nitrous oxide (N₂O), nitric oxide (NO), or a combination thereof, may flow through the processing chamber. The oxygen-containing processing gas may flow into the processing chamber continuously, or may flow into the processing chamber until a desired pressure is reached and stopped, and then maintained at that pressure during the oxidation process. The thermal oxidation treatment can be carried out at temperatures greater than 300° C. In plasma oxidation treatment, oxygen-containing processing gases such as oxygen (O₂), ozone gas (O₃), nitrous oxide (N₂O), nitric oxide (NO), or combinations thereof are used in a remote plasma source (RPS) for igniting the plasma. The oxygen-containing plasma effluent flows in the processing chamber. The gas flow, temperature and pressure in plasma oxidation treatment can be the same as in thermal oxidation treatment.

Traditional silicon oxide films are converted from silicon-based dielectrics that include high concentrations of nitrogen and/or hydrogen deposited through an FCVD process. The silicon-based dielectrics can react to form Si—O—Si bonds through annealing. However, the traditional oxidation treatment has limited ability to fill gaps with high aspect ratios and easily forms voids or seams in the gaps. In the subsequent metallization process, metal deposits (such as titanium or other metals) are easily deposited in voids or seams, causing poor reliability or quality.

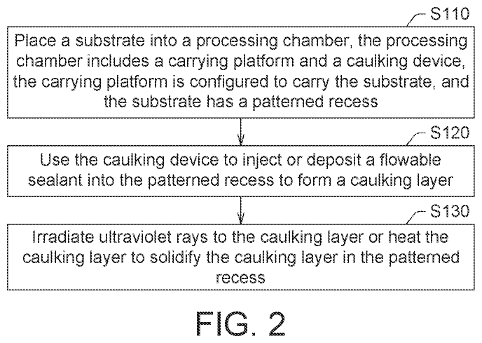

Referring to FIG. 2, a flow chart of a method for forming the caulking layer 107′ according to an embodiment of the present disclosure is illustrated. First, in step S110, the substrate 101 is placed into a processing chamber 102. The processing chamber 102 includes a carrying platform 104 and a caulking device 106. The carrying platform 104 is configured to carry a substrate 101. The substrate 101 has a patterned recess 103 (see FIG. 3A). In step S120, the caulking device 106 is configured to inject or deposit a flowable sealant 107 into the patterned recess 103 to form a caulking layer 107′. In step S130, the caulking layer 107′ is irradiated with ultraviolet rays or heated to solidify the caulking layer 107′ in the patterned recess 103.

The above method of forming the caulking layer 107′ can be performed to fill the sealant 107 into the recesses or gaps on the substrate 101 without the need for nitrogen, oxygen or hydrogen plasma. In some embodiments, a light-curable sealant material (for example, an organic polymer material such as epoxy resin) and/or a thermal-curable sealant material (such as epoxy resin) can be used as a flowable film to demonstrate this process. However, many other polymer compounds can be used alone or in any combination. The above process can be based on FCVD or pulsed plasma CVD, which imparts good filling capabilities to the desired flowable sealant 107.

In the present disclosure, it is not necessary to use a reactant gas for oxidizing the precursor. Furthermore, no reactant gases are used, but only inert gases (as carrier gas and/or diluent gas). The term “precursor” generally refers to a compound that participates in a chemical reaction to produce another compound, specifically a compound that constitutes the membrane matrix or the main structure of the membrane, while the term “reactant” refers to compounds other than the precursor. It is a reaction of an activated precursor, a modified precursor, or a catalytic precursor, wherein when RF power is applied, the reactant can provide elements (such as N, C) to the membrane matrix and become part of the membrane matrix. The term “inert gas” refers to a gas that excites the precursor when RF power is applied but, unlike the reactants, does not become part of the membrane matrix to a significant extent.

In some embodiments, a “film” refers to a layer that extends continuously in a direction perpendicular to the thickness direction and is substantially free of pores to cover the entire target or surface of interest, or a layer that covers only the target or surface of interest. In some embodiments, “layer” refers to a structure with a specific thickness formed on a surface, or is a synonym for a film or non-film structure. A film or layer may be composed of discrete single films or layers or multiple films or layers having specific properties, and the boundaries between adjacent films or layers may or may not be sharp and may or may not be based on physical, chemical and/or any other properties, the formation process or sequence and/or the function or purpose of the adjacent films or layers.

In the present disclosure, the term “filling ability” refers to the ability to substantially fill a gap without voids (e.g., without voids having a diameter of approximately 5 nm or greater) and without seams (e.g., without seams having a length of approximately 5 nm or greater). The films with filling capabilities are also called “flowable film” or “sealant 107”. The flowable or viscous behavior of the film often appears as a liquid to impart good filling capabilities. In present disclosure, recesses between adjacent protruding structures and any other pattern of recesses are referred to as “patterned recesses 103”. In other words, patterned recesses 103 include any recess pattern of holes/trenches, and may in some embodiments have a width of about 20 nm to about 100 nm (typically about 30 nm to about 50 nm), wherein when the trench has a width substantially the same as the length is called a hole/via, and its diameter can be about 20 nm to about 100 nm, its depth is about 30 nm to about 100 nm (typically about 40 nm to about 60 nm), and an aspect ratio is about 2 to about 10 (typically about 2 to about 5). The size of patterned recesses 103 may vary depending on process conditions, film composition, intended application, etc.

For example, FIGS. 3A to 3E are schematic diagrams of a method for forming a caulking layer 107′. As shown in FIG. 3A, the substrate 101 is anisotropically etched to form a patterned recess 103 in the substrate 101. The patterned recess 103 may be a trench with an aspect ratio greater than 5 or 10. Then, as shown in FIG. 3B, a liner 105 is formed in the patterned recess 103, and the liner 105 covers the sidewalls and bottom of the patterned recess 103. The liner 105 is formed by, for example, chemical vapor deposition, physical vapor deposition, or atomic layer deposition. Next, as shown in FIG. 3C, a flowable sealant 107 is formed in the patterned recess 103. The flowable sealant 107 is formed on the substrate 101 by flowable chemical vapor deposition (FCVD) or spin coating. Once all trenches, holes, or other recesses are filled, regardless of the geometry of the trench, the sealant 107 is formed by a planarizing effect and has a substantially flat surface as shown in FIG. 3C. As shown in FIG. 3D, the caulking layer 107′ in the patterned recess 103 is cured by irradiating ultraviolet light 112 or heating. Under normal temperature or heating conditions, the sealant 107 can be a light-curable or thermal-curable polymer insulation material with excellent gap-filling performance. Generally speaking, the photoinitiator (or photosensitizer) in the light-curable sealant 107 generates active free radicals or cations after absorbing ultraviolet light under ultraviolet irradiation, inducing monomer polymerization and cross-linking chemical reactions, so that the sealant 107 can converts from liquid to solid within seconds, allowing for caulking applications. Thermal-curable sealant 107 uses heat to induce monomer polymerization and cross-linking chemical reactions. Commonly used thermal-curable sealants include epoxy resin, polyester resin, vinyl ester, bismaleamide, thermosetting polyimide, cyanate ester, etc.

Next, as shown in FIG. 3E, a planarization process is performed on the cured caulking layer 107′ to remove the part protruding outside the patterned recess 103, so that the top surface of the caulking layer 107′ is substantially flush with the upper surface of the substrate 101. The planarization process, for example, uses chemical mechanical polishing tools to grind or planarize the surface of the deposited sealant. Planarization tools can be combined with polishing pads and retaining rings or with abrasive and corrosive chemical slurries.

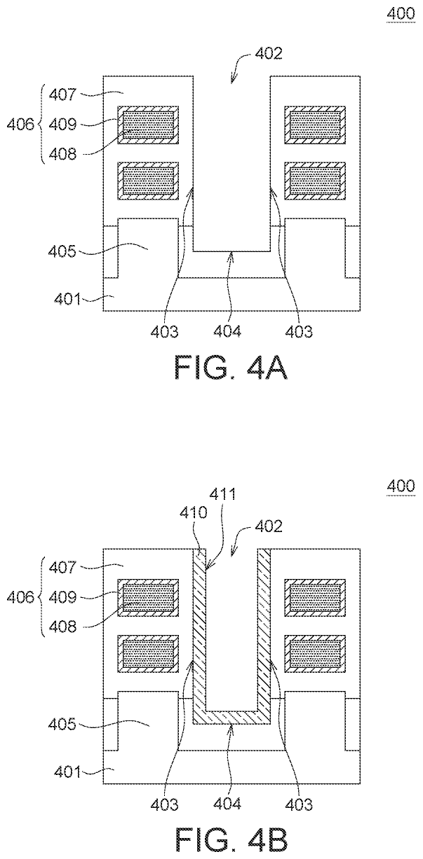

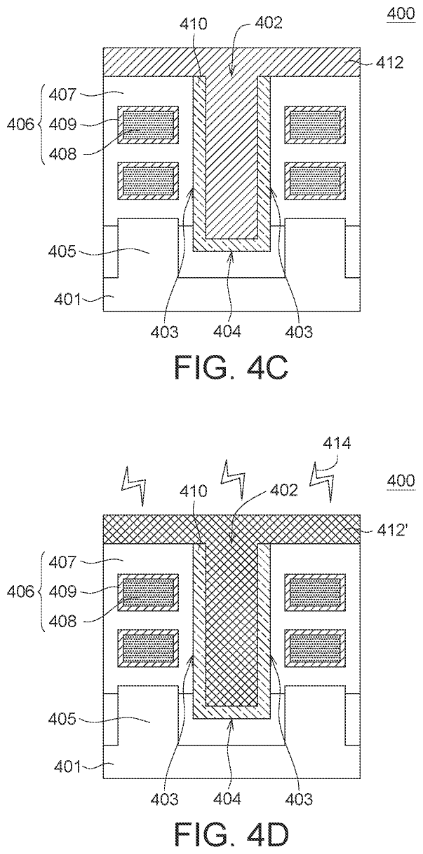

Referring to FIGS. 4A to 4D, schematic views of a method of manufacturing an electronic device (i.e., semiconductor device) according to an embodiment of the present disclosure are illustrated. In FIG. 4A, a semiconductor device 400 is formed on a substrate 401. The semiconductor device 400 includes at least one fin 405 and a gate structure 406 disposed on the fin 405. The gate structure 406 includes a gate electrode layer 407, a plurality of semiconductor layers 408 and a plurality of gate dielectric layers 409. The semiconductor layers 408 are disposed in the gate electrode layer 407, and the semiconductor layers 408 are stacked on each other and arranged at intervals. The gate dielectric layers 409 cover the semiconductor layers 408 and are electrically isolated between the gate electrode layer 407 and the semiconductor layers 408.

As shown in FIG. 4A, the gate electrode layer 407 is formed on the gate dielectric layer 409 and surrounds the gate dielectric layer 409. The gate electrode layer 407 may include a single layer or a multi-layer structure. The gate electrode layer 407 may include titanium nitride (TiN), titanium aluminum (TiAl), titanium aluminum nitride (TiAlN), tantalum nitride (TaN), Tantalum aluminum (TaAl), tantalum aluminum nitride (TaAlN), tantalum aluminum carbide (TaAlC), tantalum carbon nitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals or other suitable metal materials or combinations thereof. In addition, the gate dielectric layer 409 may include an interface layer (not shown) and a high-k gate dielectric layer. The interface layer is located on and surrounds the semiconductor layer 408, and the high-k gate dielectric layer is located on and surrounding the interface layer. In some embodiments, the interface layer includes silicon oxide. The gate dielectric layer 409 may include a high-k dielectric material, such as hafnium oxide. Alternatively, the gate dielectric layer 409 may also include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconia silicon oxide (ZrSiO₂), lanthanum oxide (La₂O₃), aluminum oxide (Al₂O₃), zirconium oxide (ZrO), yttrium oxide (Y₂O₃), SrTiO₃(STO), BaTiO₃(BTO), BaZrO, lanthanum hafnium oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃(BST), silicon nitride (SiN), silicon oxynitride (SiON), combinations thereof or other suitable materials. The gate dielectric layer 409 may be formed by any suitable method, such as CVD, ALD, PVD, other suitable techniques, or a combination thereof. At this process stage, the gate dielectric layer 409 may surround four sides of the semiconductor layer 408, and the thickness of the gate dielectric layer 409 may be about 1.5 nm to about 3 nm.

In some embodiments, the gate structure 406 includes a trench 402 that exposes two opposite sidewalls 403 and a bottom surface 404 of the gate electrode layer 407. These trenches 402 are referred to as cut metal gate (CMG) trenches in this disclosure. As semiconductor devices continue to scale down, the aspect ratio of CMG trench 402 typically increases. The cut metal gate (CMG) processes are configured to form isolation structures that divide a continuous gate into segments across multiple active regions. Such isolation structures may be referred to as gate blocking features, blocking features, or cut metal gate (CMG) features.

Next, in FIG. 4B, a patterned dielectric layer 410 (such as a liner) is covered on the semiconductor device 400. The patterned dielectric layer 410 has a recess 411, and the depth of the recess 411 is greater than the width of the recess 411. In addition, the patterned dielectric layer 410 is disposed along the opposite sidewalls 403 of the gate electrode layer 407 and covers the bottom surface 404. The patterned dielectric layer 410 can serve as a CMG isolation structure.

Subsequently, in FIG. 4C, a flowable sealant 412 is injected or deposited into the recess 411 to form a caulking layer 412′. The caulking layer 412′ includes an organic polymer insulating material. The caulking layer 412′ can be formed by spin coating, CVD, PVD, ALD or other deposition techniques. As shown in FIG. 4D, the present disclosure uses light-curable or thermal-curable sealant 412 to fill the recess 411, and the caulking layer 412′ is irradiated with ultraviolet rays 414 or heated to solidify the caulking layer 412′ in the patterned recess 411. The dielectric constant of the sealant 412 is between 2 and 2.3, which is lower than the dielectric constant of the silicon oxide film formed by traditional oxidation treatment, so that it can effectively reduce the dielectric constant of the dielectric layer. The patterned dielectric layer 410 is, for example, silicon nitride, silicon carbide, silicon oxynitride, or a combination thereof.

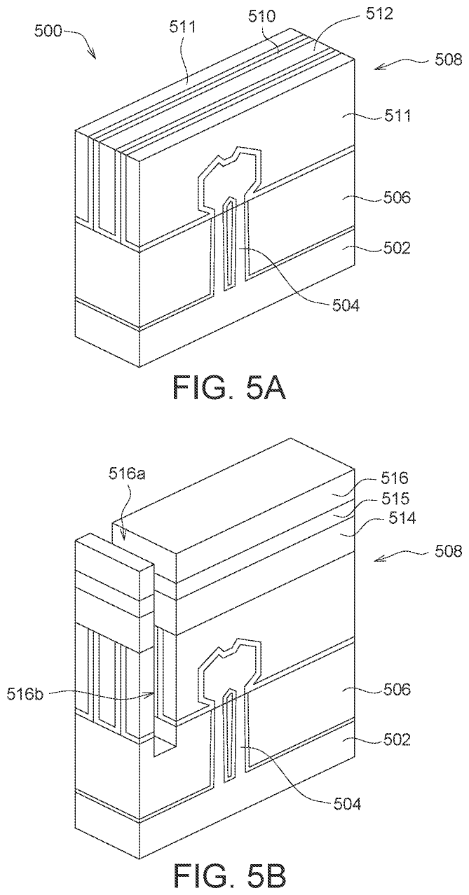

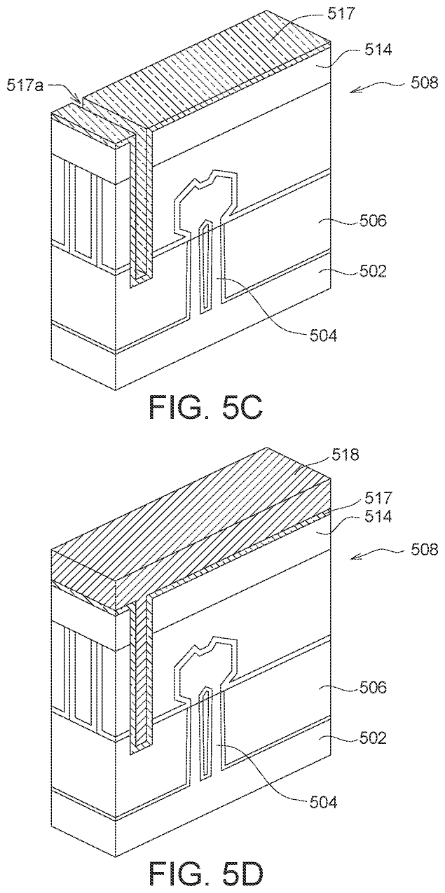

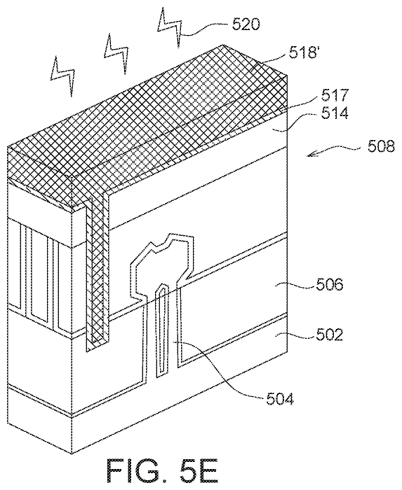

Referring to FIGS. 5A to 5E, schematic diagrams of a method of manufacturing an electronic device (i.e., semiconductor device) according to an embodiment of the present disclosure are illustrated. The semiconductor device 500 is, for example, a FinFET device. The FinFET device is a fin-based multi-gate field effect transistor, which includes a substrate 502, a plurality of fins 504 extending upward from the substrate 502, an isolation region 506, and a gate structure 508 covering the fins 504. The gate structure 508 includes a gate dielectric layer 510 and a gate electrode layer 512 formed above the gate dielectric layer 110. The gate dielectric layer 510 can be formed by chemical oxidation, thermal oxidation, atomic layer deposition (ALD), physical vapor deposition (PVD), chemical vapor deposition (CVD) and/or other suitable methods. The gate electrode layer 512 may be formed using physical vapor deposition (PVD), chemical vapor deposition (CVD), electron beam evaporation, and/or other suitable processes. In some embodiments, sidewall spacers 511 are formed on sidewalls of the gate structure 508. The sidewall spacers 511 may include dielectric materials such as silicon oxide, silicon nitride, silicon carbide, silicon oxynitride or combinations thereof.

In FIG. 5B, a hard mask layer 514 is formed on the gate structure 508. The hard mask layer 514 includes silicon nitride, silicon oxynitride, silicon carbonitride or a combination thereof, and may be a single-layer structure or a multi-layer structure.

In FIG. 5B, a photoresist layer 516 is formed on the hard mask layer 114 and the gate structure 108. By developing and removing a portion of the photoresist layer 116, the photoresist layer 116 is patterned to expose an opening 116a corresponding to at least one area to be removed. Before forming the photoresist layer 116, a bottom anti-reflection coating (BARC) 115 is formed on the hard mask layer 114 to reduce the reflection of light in the photoresist layer 116 during the exposure process. In FIG. 5B, the gate structure 108 and the hard mask layer 114 and bottom anti-reflection coating 115 covering the gate structure 108 can be partially removed through an etching process to form a deep trench 516b. The etching process includes plasma etching technology, wet chemical etching technology and/or other types of etching technology.

In FIG. 5C, a patterned dielectric layer 517 (e.g., a liner) is covered on the semiconductor device 500. The patterned dielectric layer 517 has a recess 517a disposed along opposite sidewalls of the deep trench 516b. The patterned dielectric layer 517 can serve as a CMG isolation structure.

In FIG. 5D, a flowable sealant 518 is injected or deposited into the patterned recess 517a to form a caulking layer 518′. The sealant 518 includes light-curable or thermal-curable organic polymer insulation materials. The caulking layer 518′ can be formed by spin coating, CVD, PVD, ALD or other deposition techniques. Next, in FIG. 5E, the caulking layer 518′ is irradiated with ultraviolet rays 520 or heated to solidify the caulking layer 518′ in the patterned recess 517a.

The present disclosure relates to a processing device and a method for forming a caulking layer. First, a curable sealant is formed in the shallow trench isolations (STIs) between fins on the substrate, or a curable sealant is formed in the gap between two gate structures on the substrate, or a curable sealant is formed within any patterned recesses on the substrate. Next, a lower thermal process or ultraviolet rays curing process is performed to solidify the caulking layer. The caulking layer formed by this process can be implemented, for example, in a fin field effect transistor (FinFET) to avoid voids or seams existing in the trenches or gaps.

According to some embodiments of the present disclosure, a processing device for forming a caulking layer is provided. The processing device includes a processing chamber and an ultraviolet illumination device. The processing chamber includes a carrying platform and a caulking device. The carrying platform is configured to carry a substrate, and the substrate has a patterned recess. The caulking device is configured to inject or deposit a flowable sealant into the patterned recess to form a caulking layer. The ultraviolet illumination device is configured to irradiate ultraviolet rays on the caulking layer to solidify the caulking layer in the patterned recess.

According to some embodiments of the present disclosure, a method for forming a caulking layer is provided, including the following steps. A substrate is placed into a processing chamber. The processing chamber includes a carrying platform and a caulking device. The carrying platform is configured to carry the substrate having a patterned recess. The caulking device is configured to inject or deposit a flowable sealant into the patterned recess to form a caulking layer. The caulking layer is irradiated with ultraviolet rays or heated to solidify the caulking layer in the patterned recess.

According to some embodiments of the present disclosure, a method of manufacturing an electronic device is provided, including the following steps. A semiconductor device is formed on a substrate. A patterned dielectric layer is covered on the semiconductor device. The patterned dielectric layer has a patterned recess, and the depth of the patterned recess is greater than the width of the patterned recess. A flowable sealant is injected or deposited into the patterned recess to form a caulking layer. The caulking layer is irradiated with ultraviolet rays or heated to solidify the caulking layer in the patterned recess.

According to some embodiments of the present disclosure, a semiconductor device includes a substrate having a fin, a gate structure disposed on the fin, a patterned dielectric layer and a flowable sealant. The gate structure includes a gate electrode layer, a plurality of semiconductor layers and a plurality of gate dielectric layers, wherein the semiconductor layers are disposed in the gate electrode layer, and the semiconductor layers are stacked on each other and arranged at intervals, the gate dielectric layers cover the semiconductor layers and are electrically isolated between the gate electrode layer and the semiconductor layers, wherein the gate electrode layer has a trench extended downward from a top of the gate electrode layer to expose two opposite sidewalls and a bottom surface of the gate electrode layer. The patterned dielectric layer is disposed along the opposite sidewalls of the gate electrode layer and covers the bottom surface of the gate electrode layer. The flowable sealant is injected or deposited into the trench to form a caulking layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a caulking layer, comprising:
placing a substrate into a processing chamber, wherein the processing chamber comprises a carrying platform and a caulking device, the carrying platform is configured to carry a substrate, and the substrate has a patterned recess;
using the caulking device to inject or deposit a flowable sealant into the patterned recess to form a caulking layer; and
irradiating the caulking layer with ultraviolet rays or heating the caulking layer to solidify the caulking layer in the patterned recess.

2. The method for forming a caulking layer of claim 1, wherein the caulking device comprises a glue dispenser, and the flowable sealant is formed on the substrate by spin coating.

3. The method for forming a caulking layer of claim 1, wherein the caulking device comprises a vapor deposition device, and the flowable sealant is formed on the substrate by a flowable chemical vapor deposition method.

4. The method for forming a caulking layer of claim 1, wherein the flowable sealant comprises light-curable sealant.

5. The method for forming a caulking layer of claim 1, wherein the flowable sealant comprises a thermal-curable sealant.

6. The method for forming a caulking layer of claim 1, further comprising forming a liner in the patterned recess before injecting or depositing the flowable sealant.

7. A method of manufacturing an electronic device, comprising:
forming a semiconductor device on a substrate;
covering the semiconductor device with a patterned dielectric layer, the patterned dielectric layer having a patterned recess, a depth of the patterned recess being greater than a width of the patterned recess;
injecting or depositing a flowable sealant into the patterned recess to form a caulking layer; and
irradiating the caulking layer with ultraviolet rays or heating the caulking layer to solidify the caulking layer in the patterned recess.

8. The method of claim 7, wherein the flowable sealant is formed on the substrate by spin coating.

9. The method of claim 7, wherein the flowable sealant is formed on the substrate by a flowable chemical vapor deposition method.

10. The method of claim 7, wherein the flowable sealant comprises a light-curable sealant.

11. The method of claim 7, wherein the flowable sealant comprises a thermal-curable sealant.

12. The method of claim 7, wherein the semiconductor device comprises at least one fin and a gate structure disposed on the fin, the gate structure comprises a trench, and the patterned recess and the caulking layer are formed in the trench.

13. The method of claim 12, wherein the patterned dielectric layer serves as a cut metal gate isolation structure.

14. The method of claim 12, wherein the gate structure comprises a gate electrode layer, the trench exposes two opposite sidewalls and a bottom surface of the gate electrode layer, and the patterned recess is disposed along the two opposite sidewalls of the gate electrode layer and covers the bottom surface.

15. The method of claim 14, wherein the patterned dielectric layer serves as a cut metal gate isolation structure.

16. A semiconductor device, comprising:
a substrate having a fin;
a gate structure disposed on the fin, the gate structure comprising a gate electrode layer, a plurality of semiconductor layers and a plurality of gate dielectric layers, wherein the semiconductor layers are disposed in the gate electrode layer, and the semiconductor layers are stacked on each other and arranged at intervals, the gate dielectric layers cover the semiconductor layers and are electrically isolated between the gate electrode layer and the semiconductor layers,
wherein the gate electrode layer has a trench extended downward from a top of the gate electrode layer to expose two opposite sidewalls and a bottom surface of the gate electrode layer;
a patterned dielectric layer disposed along the opposite sidewalls of the gate electrode layer and covers the bottom surface of the gate electrode layer; and
a flowable sealant injected or deposited into the trench to form a caulking layer.

17. The semiconductor device of claim 16, wherein the caulking layer is irradiated with ultraviolet rays or heated to solidify the caulking layer.

18. The semiconductor device of claim 16, wherein the caulking layer is made of a light-curable or thermal-curable organic polymer insulation material.

19. The semiconductor device of claim 16, wherein the patterned dielectric layer serves as a cut metal gate isolation structure.

20. The semiconductor device of claim 16, wherein the flowable sealants is selected from a group consisting of epoxy resin, polyester resin, vinyl ester, bismaleamide, thermosetting polyimide and cyanate ester.
